(19) United States
(12) Patent Application Publication
(10) Pub. No.: US 2008/0017881 A1
(43) Pub. Date: Jan. 24, 2008

(54) Power supplying and discharging circuit

(75) Inventor: Kun Le, Shenzhen (CN)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 11/824,886

(22) Filed: Jul. 2, 2007

(30) Foreign Application Priority Data
Jun. 30, 2006 (TW) 95123842

(51) Int. Cl. H01L 29/74

(52) U.S. Cl. 257/123

(57) ABSTRACT

An exemplary power supplying and discharging circuit (200) includes a control signal input terminal (21), an output terminal (26), a direct current (DC) power supply (22), a bias resistor (27), a first transistor (23), a second transistor (24), and a third transistor (25). The first transistor includes a base electrode connected to the control signal input terminal, a collector electrode connected to the DC power supply via the bias transistor, and an emitter electrode grounded. The second transistor includes a base electrode connected to the collector electrode of the first transistor, a collector electrode connected to the output terminal, and an emitter electrode grounded. The third transistor includes a gate electrode connected to the collector electrode of the first transistor, a source electrode connected to the DC power supply, and a drain electrode connected to the output terminal.

### FIELD OF THE INVENTION

The present invention relates to power supplying and discharging circuits, and particularly to a power supplying and discharging circuit employing a direct current (DC) power supply.

### GENERAL BACKGROUND

A liquid crystal display (LCD) has the advantages of portability, low power consumption, and low radiation, and has been widely used in various portable information products such as notebooks, personal digital assistants (PDAs), video cameras and the like. Furthermore, the LCD is considered by many to have the potential to completely replace CRT (cathode ray tube) monitors and televisions.

A typical LCD includes an LCD panel. The LCD panel includes a plurality of pixels, each of which has a capacitor. An external power supply provides an operation voltage to the LCD. When the power supply is turned off, the operation voltage in a rudimentary LCD does not immediately decrease. For example, when a power supply providing a voltage of 5V is turned off, the voltage in the LCD decreases from 5V to a residual voltage of 0.4V, and this takes about 20 seconds. If the power supply is turned on again before the residual voltage in the LCD has decreased to a predetermined threshold voltage, this is liable to cause an operational error in the LCD. To avoid such operational error, a typical modern LCD is provided with a power supplying and discharging circuit. The power supplying and discharging circuit enables the residual voltage to be removed from the LCD quickly.

FIG. 3 is a diagram of a conventional power supplying and discharging circuit used in an LCD. The power supplying and discharging circuit 100 includes a control signal input terminal 11 configured for receiving a control signal, an output terminal 16 configured for connecting to a load circuit (not shown) such as an LCD, a five volt DC power supply 12 functioning as a main power source of the load circuit, a positive-negative-positive (PNP) transistor 13, a negative-positive-negative (NPN) transistor 14, a p-channel enhancement mode metal-oxide-semiconductor (PMOS) transistor 15, a bias resistor 17, and a discharging resistor 18.

The PNP transistor 13 includes a base electrode “b” connected to the control signal input terminal 11 via a resistor (not labeled), a collector electrode “c” that is grounded, and an emitter electrode “e” connected to the DC power supply 12 via the bias resistor 17.

The NPN transistor 14 includes a base electrode “b” connected to the control signal input terminal 11 via a resistor (not labeled), an emitter electrode “e” that is grounded, and a collector electrode “c” connected to the output terminal 16 via the discharging resistor 18.

The PMOS transistor 15 includes a gate electrode “g” connected to the emitter electrode “e” of the PNP transistor 13, a source electrode “s” connected to the DC power supply 12, and a drain electrode “d” connected to the output terminal 16.

In order to apply the 5V voltage from the DC power supply 12 to the output terminal 16, a first control signal such as a low level 0V voltage is provided to the control signal input terminal 11 by an external circuit (not shown). Thus the PNP transistor 13 is switched on, and the NPN transistor 14 is switched off. The gate electrode “g” of the PMOS transistor 15 is connected to ground via the activated PNP transistor 13. A voltage difference between the gate electrode “g” and the source electrode “s” of the PMOS transistor 15 is approximately equal to −5V, thus the PMOS transistor 15 is switched on. Accordingly, the 5V voltage from the DC power supply 12 is provided to the output terminal 16 via the activated PMOS transistor 15.

In order to suspend the supply of the 5V voltage from the DC power supply 12 to the output terminal 16, a second control signal such as a high level 5V voltage is provided to the control signal input terminal 11 by the external circuit. Thus the PNP transistor 13 is switched off, and the NPN transistor 14 is switched on. The gate electrode “g” of the PMOS transistor 15 is connected to the DC power supply 12. A voltage difference between the gate electrode “g” and the source electrode “s” of the PMOS transistor 15 is approximately equal to 0V, thus the PMOS transistor 15 is switched off. Therefore, the 5V voltage from the DC power supply 12 cannot be provided to the output terminal 16. Electric charges stored in the load circuit can be quickly discharged through the actived NPN transistor 14.

Because the PNP transistor 13 and the NPN transistor 14 are controlled by the control signal input terminal 11 synchronously, when the first control signal or the second control signal is wrong (e.g. the first control signal or the second control signal is 2.5V voltage), the PNP transistor 13 and the NPN transistor 14 are liable to be switched on at the same time. Then the PMOS transistor 15 is switched on correspondingly, and the DC power supply 12 is short-circuited to ground. When this happens, the internal circuitry of the LCD is liable to be damaged or destroyed.

It is desired to provide a new power supplying and discharging circuit which can overcome the above-described deficiencies.

### SUMMARY

In one aspect, a power supplying and discharging circuit includes a control signal input terminal configured for receiving a control signal, an output terminal configured to be connected to a load circuit, a direct current (DC) power supply, a bias transistor, a first transistor, a second transistor, and a third transistor. The first transistor includes a control electrode connected to the control signal input terminal, a first current conducting electrode connected to the DC power supply via the bias transistor, and a second current conducting electrode grounded. The second transistor includes a control electrode connected to the first current conducting electrode of the first transistor, a first current conducting electrode connected to the output terminal, and a second current conducting electrode grounded. The third transistor includes a control electrode connected to the first current conducting electrode of the first transistor, a first current conducting electrode connected to the DC power supply, and a second current conducting electrode connected to the output terminal.

In another aspect, a power supplying and discharging circuit includes a control signal input terminal configured for receiving a control signal, an output terminal configured to be connected to a load circuit, a direct current (DC) power supply, a first switch connected to the control signal input terminal, a second switch connected between the output terminal and the ground, and a third switch connected between the output terminal and the DC power supply. The second switch is switched off and the third switch is switched on when the first switch is switched on, and the second switch is switched on and the third switch is switched off when the first switch is switched off.

Other novel features and advantages will become more apparent from the following detailed description when taken in conjunction with the accompanying drawings.

### BRIEF DESCRIPTION OF THE DRAWINGS

FIG. 1 is a circuit diagram of a power supplying and discharging circuit according to a first embodiment of the present invention, the power supplying and discharging circuit being typically used in an LCD.

FIG. 2 is a circuit diagram of a power supplying and discharging circuit according to a second embodiment of the present invention, the power supplying and discharging circuit being typically used in an LCD.

FIG. 3 is a circuit diagram of a conventional power supplying and discharging circuit used in an LCD.

### DETAILED DESCRIPTION OF PREFERRED EMBODIMENTS

Reference will now be made to the drawings to describe the present invention in detail.

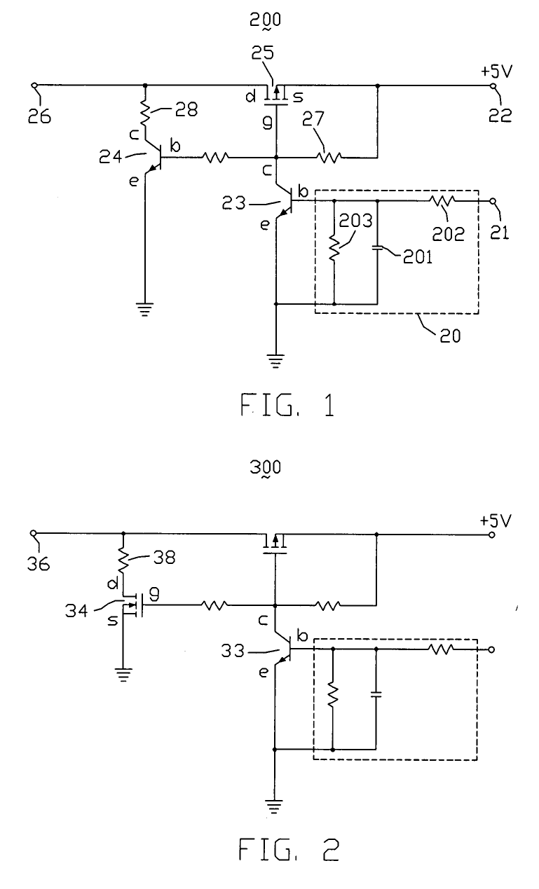

FIG. 1 is a circuit diagram of a power supplying and discharging circuit according to a first embodiment of the present invention. The power supplying and discharging circuit 200 is typically used in an LCD. The power supplying and discharging circuit 200 includes a control signal input terminal 21 configured for receiving a control signal, an output terminal 26 configured for connecting to a load circuit (not shown) such as an LCD, a five volt DC power supply 22 functioning as a main power source of the load circuit, a first transistor 23, a second transistor 24, a third transistor 25, a bias resistor 27, a discharging resistor 28, and a protection circuit 20. The first and second transistors 23, 24 are negative-positive-negative (NPN) transistors, and the third transistor 25 is a p-channel enhancement mode metal-oxide-semiconductor (PMOS) transistor.

The first transistor 23 includes a base electrode “b” connected to the control signal input terminal 21 via the protection circuit 20, a collector electrode “c” connected to the DC power supply 22 via the bias resistor 27, and an emitter electrode “e” that is grounded.

The second transistor 24 includes a base electrode “b” connected to the collector electrode “c” of the first transistor 23 via a resistor (not labeled), an emitter electrode “e” that is grounded, and a collector electrode “c” connected to the output terminal 26 via the discharging resistor 28.

The third transistor 25 includes a gate electrode “g” connected to the collector electrode “c” of the first transistor 23, a source electrode “s” connected to the DC power supply 22, and a drain electrode “d” connected to the output terminal 26.

The protection circuit 20 includes a capacitor 201, a first resistor 202, and a second resistor 203. The capacitor 201 is connected between the base electrode “b” of the first transistor 23 and ground. The first resistor 202 is connected between the control signal input terminal 21 and the base electrode “b” of the first transistor 23. The second resistor 203 is connected between the base electrode “b” of the first transistor 23 and ground.

In order to apply the 5V voltage from the DC power supply 22 to the output terminal 26, a first control signal such as a high level 5V voltage is provided to the control signal input terminal 21 by an external circuit (not shown). Thus the first transistor 23 is switched on, and the base electrode “b” of the second transistor 24 and the gate electrode “g” of the third transistor 25 are both pulled down to a low voltage state via the activated first transistor 23. The second transistor 24 is switched off, and the third transistor 25 is switched on. Accordingly, the 5V voltage from the DC power supply 22 is provided to the output terminal 26 via the activated third transistor 25.

In order to suspend the supply of the 5V voltage from the DC power supply 22 to the output terminal 26, a second control signal such as a low level 0V voltage is provided to the control signal input terminal 21 by the external circuit. Thus the first transistor 23 is switched off. The base electrode “b” of the second transistor 24 is connected to the DC power supply 22, therefore the second transistor 24 is switched on. The gate electrode “g” of the third transistor 25 is connected to the DC power supply 22. A voltage difference between the gate electrode “g” and the source electrode “s” of the third transistor 25 is approximately equal to 0V, therefore the third transistor 25 is switched off. Thus, the 5V voltage from the DC power supply 22 cannot be provided to the output terminal 26. Electric charges stored in the load circuit can be quickly discharged through the actived second transistor 24.

When the control signal provided to the control signal input terminal 21 by the external circuit changes quickly, the first resistor 202 and the capacitor 201 of the protection circuit 20 are equivalent to a buffer circuit that can stop the first transistor 23 from being switched on suddenly. Thus when the 5V voltage from the DC power supply 22 is provided to the load circuit, a sudden rush of electrical in the load circuit is avoided. That is, circuitry of the LCD is protected from damage or destruction.

When the control signal input terminal 21 is in a suspended state (i.e. when no control signal is provided to the control signal input terminal 21), the second resistor 203 can maintain the base electrode “b” of the first transistor 23 in a low voltage state. Therefore the first transistor 23 is switched off stably.

Because the second transistor 24 is controlled by the first transistor 23, when the first transistor 23 is switched on, the second transistor 24 is switched off securely. Moreover, when the first transistor 23 is switched off, the second transistor 24 is switched on securely. Thereby, the internal circuitry of the LCD is securely protected.

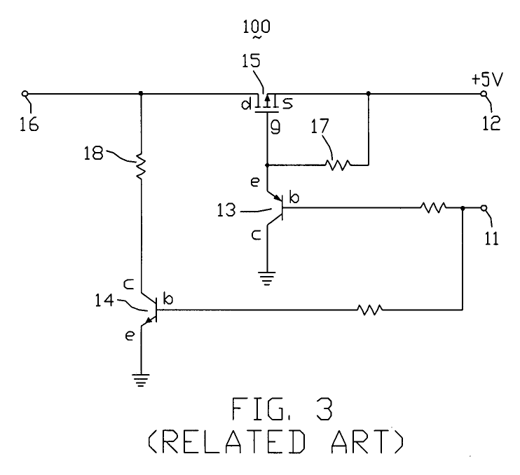

FIG. 2 is a circuit diagram of a power supplying and discharging circuit according to a second embodiment of the present invention. The power supplying and discharging circuit 300 is typically used in an LCD, and is similar to the power supplying and discharging circuit 200. However, a unique characteristic of the power supplying and discharging circuit 300 is that a second transistor 34 is an n-channel enhancement mode metal-oxide-semiconductor (NMOS) transistor. The second transistor 34 includes a gate electrode “g” connected to a collector electrode “c” of a first transistor 33 via a resistor (not labeled), a source electrode “s” that is grounded, and a drain electrode “d” connected to an output terminal 36 via a discharging resistor 38. The power supplying and discharging circuit 300 has functionality and advantages similar to those of the power supplying and discharging circuit 200.

In each of the power supplying and discharging circuits 200, 300, any one or more of the first, second, and third transistors 23, (33), 24, (34), 25 can be replaced by another kind of switch, for example a three way switch. In other alternative embodiments, the discharging resistor 28 (38) can be omitted.

It is to be further understood that even though numerous characteristics and advantages of preferred and exemplary embodiments have been set out in the foregoing description, together with details of the structures and functions of the embodiments, the disclosure is illustrative only; and that changes may be made in detail, especially in matters of arrangement of parts within the principles of present invention to the full extent indicated by the broad general meaning of the terms in which the appended claims are expressed.

What is claimed is:

1. A power supplying and discharging circuit, comprising:
a control signal input terminal configured for receiving a control signal;
an output terminal configured to be connected to a load circuit;
a direct current (DC) power supply;
a bias resistor;
a first transistor comprising a control electrode connected to the control signal input terminal, a first current conducting electrode connected to the DC power supply via the bias resistor, and a second current conducting electrode that is configured to be grounded;
a second transistor comprising a control electrode connected to the first current conducting electrode of the first transistor, a first current conducting electrode connected to the output terminal, and a second current conducting electrode that is configured to be grounded; and
a third transistor comprising a control electrode connected to the first current conducting electrode of the first transistor, a first current conducting electrode connected to the DC power supply, and a second current conducting electrode connected to the output terminal.

2. The power supplying and discharging circuit as claimed in claim 1, wherein the first transistor is a negative-positive-negative (NPN) transistor.

3. The power supplying and discharging circuit as claimed in claim 2, wherein the control electrode of the first transistor is a base electrode of the NPN transistor, the first current conducting electrode of the first transistor is a collector electrode of the NPN transistor, and the second current conducting electrode of the first transistor is an emitter electrode of the NPN transistor.

4. The power supplying and discharging circuit as claimed in claim 1, wherein the second transistor is a negative-positive-negative (NPN) transistor.

5. The power supplying and discharging circuit as claimed in claim 4, wherein the control electrode of the second transistor is a base electrode of the NPN transistor, the first current conducting electrode of the second transistor is a collector electrode of the NPN transistor, and the second current conducting electrode of the second transistor is an emitter electrode of the NPN transistor.

6. The power supplying and discharging circuit as claimed in claim 1, wherein the second transistor is an n-channel enhancement mode metal-oxide-semiconductor (NMOS) transistor.

7. The power supplying and discharging circuit as claimed in claim 6, wherein the control electrode of the second transistor is a gate electrode of the NMOS transistor, the first current conducting electrode of the second transistor is a collector electrode of the NMOS transistor, and the second current conducting electrode of the second transistor is a drain electrode of the NMOS transistor.

8. The power supplying and discharging circuit as claimed in claim 1, wherein the third transistor is a p-channel enhancement mode metal-oxide-semiconductor (PMOS) transistor.

9. The power supplying and discharging circuit as claimed in claim 8, wherein the control electrode of the third transistor is a gate electrode of the PMOS transistor, the first current conducting electrode of the third transistor is a collector electrode of the PMOS transistor, and the second current conducting electrode of the third transistor is a drain electrode of the PMOS transistor.

10. The power supplying and discharging circuit as claimed in claim 1, further comprising a discharging resistor connected between the first current conducting electrode of the second transistor and the output terminal.

11. The power supplying and discharging circuit as claimed in claim 10, further comprising a protection circuit connected between the control electrode of the first transistor and the control signal input terminal.

12. The power supplying and discharging circuit as claimed in claim 11, wherein the protection circuit comprises a capacitor connected between the control electrode of the first transistor and ground, a first resistor connected between the control signal input terminal and the control electrode of the first transistor, and a second resistor connected between the control electrode of the first transistor and ground.

13. The power supplying and discharging circuit as claimed in claim 1, further comprising a resistor connected between the first current conducting electrode of the first transistor and the control electrode of the second transistor.

14. The power supplying and discharging circuit as claimed in claim 1, wherein the DC power supply is a five volt DC power supply.

15. The power supplying and discharging circuit as claimed in claim 1, wherein the load circuit is a liquid crystal display.

16. A power supplying and discharging circuit, comprising:
a control signal input terminal configured for receiving a control signal;
an output terminal configured to be connected to a load circuit;
a direct current (DC) power supply;
a first switch connected to the control signal input terminal;
a second switch configured to be connected between the output terminal and the ground; and
a third switch connected between the output terminal and the DC power supply;
wherein the second switch is switched off and the third switch is switched on when the first switch is switched on, and the second switch is switched on and the third switch is switched off when the first switch is switched off.

17. The power supplying and discharging circuit as claimed in claim 16, further comprising a bias resistor, wherein the first switch is a first transistor, and the first transistor comprises a control electrode connected to the control signal input terminal, a first current conducting electrode connected to the DC power supply via the bias resistor, and a second current conducting electrode configured to be grounded.

18. The power supplying and discharging circuit as claimed in claim 17, wherein the second switch is a second transistor, and the second transistor comprises a control electrode connected to the first current conducting electrode of the first transistor, a first current conducting electrode connected to the output terminal, and a second current conducting electrode configured to be grounded.

19. The power supplying and discharging circuit as claimed in claim 18, wherein the third switch is a third transistor, and the third transistor comprises a control electrode connected to the first current conducting electrode of the first transistor, a first current conducting electrode connected to the DC power supply, and a second current conducting electrode connected to the output terminal.

20. A power supplying and discharging circuit, comprising:
a control signal input terminal configured for receiving a control signal;
an output terminal configured to be connected to a load circuit;
a direct current (DC) power supply;
a bias resistor;
a first transistor comprising a control electrode connected to the control signal input terminal, a first current conducting electrode connected to the DC power supply via the bias resistor, and a second current conducting electrode that is configured to be grounded;
a second transistor comprising a control electrode connected to the first current conducting electrode of the first transistor, a first current conducting electrode connected to the output terminal, and a second current conducting electrode that is configured to be grounded; and
a protection circuit including parallel connected resistor and capacitor commonly serially connected to another resistor, said protection circuit connected between the control signal input terminal and the first transistor.
